(19) United States
(12) Patent Application Publication
(10) Pub. No.: US 2012/0236167 A1
(43) Pub. Date: Sep. 20, 2012

(54) FLEXIBLE WIRING STRUCTURE, FLEXIBLE WIRING METHOD, AND IMAGING DEVICE

(75) Inventors: Hisanori TAKANO, Tokyo (JP); Hiroyuki SHISHIDO, Tokyo (JP)

(73) Assignee: OLYMPUS CORPORATION, Tokyo (JP)

(21) Appl. No.: 13/414,815

(22) Filed: Mar. 8, 2012

(30) Foreign Application Priority Data
Mar. 18, 2011 (JP) 2011-061536

(51) Int. Cl. H04N 5/335; H04N 5/225; H05K 3/00; H05K 1/02

(52) U.S. Cl. 348/208.2; 174/254; 348/294; 29/829; 348/E05.091; 348/E05.024

(57) ABSTRACT

A flexible wiring structure includes a first and a second flexible wiring section divided with a relay section provided on one end side of an L-shaped section of a flexible wire having the L-shaped section. The first flexible wiring section includes a first raised surface and a first post-bend raised surface bent in a first bent section, which is a bent section of the L-shaped section, from the first raised surface. The second flexible wiring section includes a second raised surface and a second post-bend raised surface bent in a second bent section, which is a bent section of the L-shaped section and provided above the first bent section, from the second raised surface and parallel to the first post-bend raised surface. The second post-bend raised surface is folded back in a raised surface bending section provided on the second raised surface and overlaps the first post-bend raised surface.

### CROSS REFERENCE TO RELATED APPLICATIONS

This application claims benefit of Japanese Application No. 2011-061536 filed on Mar. 18, 2011, the contents of which are incorporated by this reference.

### BACKGROUND OF THE INVENTION

1. Field of the Invention

The present invention relates particularly to a flexible wiring structure concerning routing of a flexible wire and an imaging device including the flexible wiring structure.

2. Description of the Related Art

In a camera shake correction function, a movable unit to which an imaging element or an optical component is attached moves in a direction for cancelling the movement of an imaging module caused by a camera shake to suppress a deflection of an image. The movable unit is moved by an actuator such as a voice coil motor or a stepping motor.

In order to electrically connect the movable section and a control circuit board and suppress a load of the movement of the movable section, a flexible wiring board provided with a bent section is used (see, for example, Patent Document 1 (Japanese Laid-Open Patent Publication No. 2009-128521)).

In the flexible wiring board described in Patent Document 1, the bent section is formed only at an angle of 90° in order to suppress reaction and a first flexible board section and a second flexible board section, which are divided with a relay board section provided therein, stand with the relay board section side set at the top.

### SUMMARY OF THE INVENTION

A flexible wiring structure according to an aspect of the present invention includes a first flexible wiring section and a second flexible wiring section divided with a relay section provided on one end side of an L-shaped section of a flexible wire having the L-shaped section. The first flexible wiring section includes a first raised surface raised from a plane of the relay section via a first relay side bending section provided on the relay section side and a first post-bend raised surface bent in a first bent section, which is a bent section of the L-shaped section, from the first raised surface. The second flexible wiring section includes a second raised surface raised from the plane of the relay section via a second relay side bending section provided on the relay section side and a second post-bend raised surface bent in a second bent section, which is a bent section of the L-shaped section and provided above the first bent section, from the second raised surface and parallel to the first post-bend raised surface. The second post-bend raised surface is folded back in a raised surface bending section provided on the second raised surface and overlaps the first post-bend raised surface.

An imaging device according to another aspect of the present invention is an imaging device including a flexible wiring structure and an imaging element that is connected to the flexible wiring structure and images incident light and outputs an imaging signal. The flexible wiring structure includes a first flexible wiring section and a second flexible wiring section divided with a relay section provided on one end side of an L-shaped section of a flexible wire having the L-shaped section. The first flexible wiring section includes a first raised surface raised from a plane of the relay section via a first relay side bending section provided on the relay section side and a first post-bend raised surface bent in a first bent section, which is a bent section of the L-shaped section, from the first raised surface. The second flexible wiring section includes a second raised surface raised from the plane of the relay section via a second relay side bending section provided on the relay section side and a second post-bend raised surface bent in a second bent section, which is a bent section of the L-shaped section and provided above the first bent section, from the second raised surface and parallel to the first post-bend raised surface. The second post-bend raised surface is folded back in a raised surface bending section provided on the second raised surface and overlaps the first post-bend raised surface.

A flexible wiring method according to still another aspect of the present invention includes: forming a first flexible wiring section and a second flexible wiring section divided with a relay section provided on one end side of an L-shaped section of a flexible wire having the L-shaped section; forming, in the first flexible wiring section, a first raised surface raised from a plane of the relay section via a first relay side bending section provided on the relay section side and a first post-bend raised surface bent in a first bent section, which is a bent section of the L-shaped section, from the first raised surface; forming, in the second flexible wiring section, a second raised surface raised from the plane of the relay section via a second relay side bending section provided on the relay section side and a second post-bend raised surface bent in a second bent section, which is a bent section of the L-shaped section and provided above the first bent section, from the second raised surface and parallel to the first post-bend raised surface; and folding back the second post-bend raised surface in a raised surface bending section provided on the second raised surface and placing the second-post-bend raised surface on the first post-bend raised surface.

### BRIEF DESCRIPTION OF THE DRAWINGS

FIG. 1 is a perspective view showing an imaging device according to a first embodiment of the present invention;

FIG. 2 is a front view showing the imaging device according to the first embodiment of the present invention;

FIG. 3 is a plan view showing the imaging device according to the first embodiment of the present invention;

FIG. 4 is a sectional view taken along IV-IV in FIG. 3;

FIG. 5A is a first main part perspective view showing a flexible wiring structure according to the first embodiment of the present invention;

FIG. 5B is a second main part perspective view showing the flexible wiring structure according to the first embodiment of the present invention;

FIG. 5C is a main part rearview showing the flexible wiring structure according to the first embodiment of the present invention;

FIG. 6 is a main part exploded view showing the flexible wiring structure according to the first embodiment of the present invention;

FIG. 7A is a first explanatory diagram for explaining a bending method for the flexible wiring structure according to the first embodiment of the present invention;

FIG. 7B is a second explanatory diagram for explaining the bending method for the flexible wiring structure according to the first embodiment of the present invention;

FIG. 8 is a main part exploded view showing a flexible wiring structure according to a second embodiment of the present invention;

FIG. 9A is a first explanatory diagram for explaining a bending method for the flexible wiring structure according to the second embodiment of the present invention;

FIG. 9B is a second explanatory diagram for explaining the bending method for the flexible wiring structure according to the second embodiment of the present invention;

FIG. 9C is a third explanatory diagram for explaining the bending method for the flexible wiring structure according to the second embodiment of the present invention;

FIG. 10A is a first main part perspective view showing a flexible wiring structure according to a third embodiment of the present invention;

FIG. 10B is a second main part perspective view showing the flexible wiring structure according to the third embodiment of the present invention;

FIG. 11 is a main part exploded view showing the flexible wiring structure according to the third embodiment of the present invention;

FIG. 12A is a first explanatory diagram for explaining a bending method for the flexible wiring structure according to the third embodiment of the present invention; and

FIG. 12B is a second explanatory diagram for explaining the bending method for the flexible wiring structure according to the third embodiment of the present invention.

### DETAILED DESCRIPTION OF THE PREFERRED EMBODIMENTS

Flexible wiring structures and imaging devices according to embodiments of the present invention are explained below with reference to the accompanying drawings.

### First Embodiment

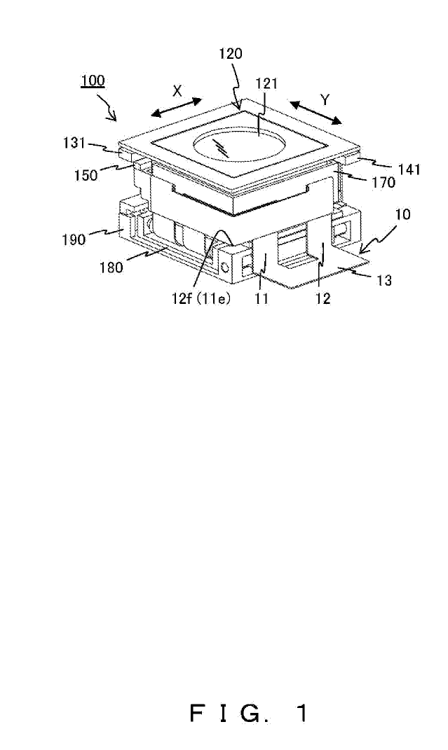

FIGS. 1, 2, and 3 are a perspective view, a front view, and a plan view showing an imaging device 100 according to the first embodiment.

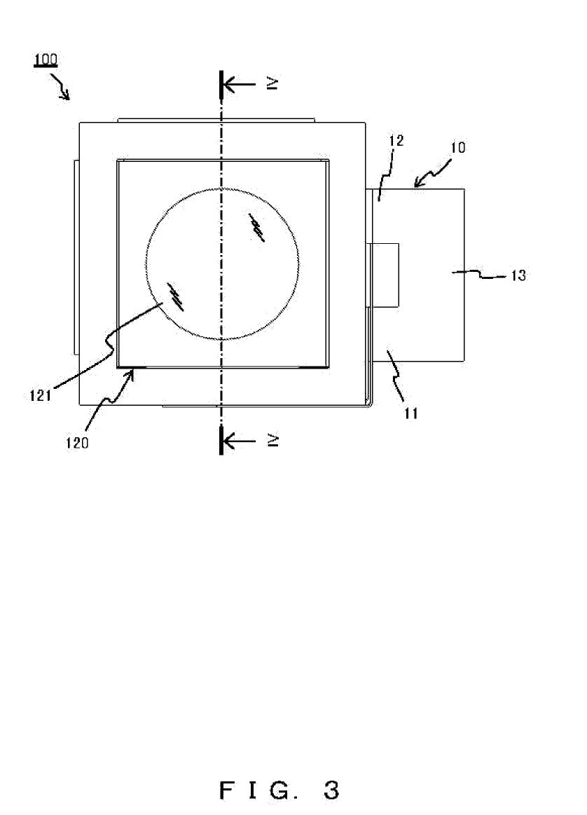

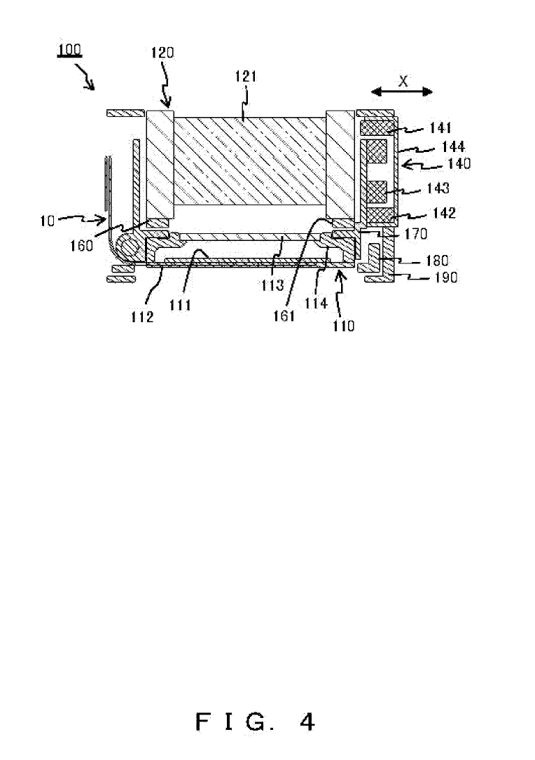

FIG. 4 is a sectional view taken along IV-IV in FIG. 3.

In this embodiment, first, the imaging device 100 including a flexible wiring structure 10 is explained.

As shown in FIGS. 1 to 4, the imaging device 100 includes the flexible wiring structure 10, an imaging element unit 110 including an imaging element 111, a lens unit 120 including a lens 121, which is an example of an optical component, a Y direction driving section 130 and an X direction driving section 140, which are examples of a driving section, a detecting section 150, a holder 160, a Y direction slider 170, an X direction slider 180, and a base section 190. The imaging device 100 is arranged in, for example, a cellular phone and a small DSC (Digital Still Camera).

As shown in FIG. 4, the imaging element unit 110 includes the imaging element 111, a base substrate 112, a cover glass 113, and a cover glass holder 114.

The imaging element 111 is mounted on the base substrate 112, images incident light, and outputs an imaging signal. The cover glass 113, which is a light transmissive cover, is arranged above the imaging element 111. The cover glass 113 is held by the cover glass holder 114.

As explained in detail later, the flexible wiring structure 10 is connected to the imaging element 111 via the base substrate 112.

The lens unit 120 includes the lens 121 that focuses incident light on an imaging surface of the imaging element 111 and a not-shown autofocus actuator, which is, for example, a voice coil motor.

The lens unit 120 is fixed to the upper surface of the holder 160 by, for example, bonding. The holder 160 is fixed to the base section 190. Therefore, like the holder 160 and the base section 190, the lens unit 120 does not move onto the same plane as the imaging surface of the imaging element 111.

The lens 121 is moved in an incident light axis direction by, for example, the autofocus actuator.

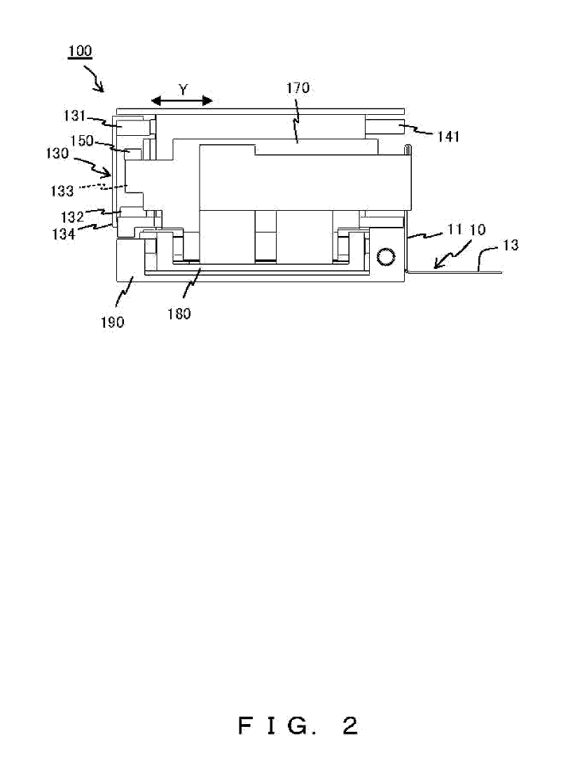

As shown in FIG. 2, the Y direction driving section 130 is a voice coil motor and includes magnets 131 and 132 opposed to each other, a coil 133, and a yoke 134. As shown in FIG. 4, like the Y direction driving section 130, the X direction driving section 140 includes magnets 141 and 142 opposed to each other, a coil 143, and a yoke 144.

The Y direction driving section 130 and the X direction driving section 140 are arranged around the lens unit 120.

The coils 133 and 143 of the Y direction driving section 130 and the X direction driving section 140 are fixed to the outer circumferential surface of the Y direction slider 170.

On the other hand, the magnets 131, 132, 141, and 142 and the yokes 134 and 144 are directly or indirectly fixed to the base section 190.

The yokes 134 and 144 assume a square shape in section that surrounds the magnets 131, 132, 141, and 142 and the coils 133 and 143 and opens on the lens unit 120 side.

As shown in FIG. 4, the Y direction slider 170 assumes a rectangular parallelepiped shape that opens on the upper surface and the bottom surface. The lens unit 120 is arranged on the inside of the Y direction slider 170. The imaging element unit 110 is fixed to a lower part of the Y direction slider 170 by, for example, bonding in an upper part of the cover glass holder 114. Since the imaging element 111 is indirectly arranged in the Y direction slider 170 in this way, the imaging element 111 moves integrally with the Y direction slider 170.

The Y direction slider 170 is moved in the Y direction with respect to the X direction slider 180 by the Y direction driving section 130 shown in FIG. 2. The Y direction slider 170 is moved in the X direction together with the X direction slider 180 by the X direction driving section 140 shown in FIG. 4. In this way, the imaging element 111 moves in the Y direction and the X direction, i.e., onto the same plane as the imaging surface of the imaging element 111 integrally with the Y direction slider 170.

The detecting section 150 shown in FIG. 1 is, for example, a Hall element and is arranged near the Y direction driving section 130. The detecting section 150 detects a movement amount of the Y direction slider 170 to detect a movement amount of the imaging device 111.

In FIG. 4, hatching representing a cross section and the like is shown. However, materials of the sections are not limited by types of the hatching. For example, an example of the material of the holder 160, the Y direction slider 170, the X direction slider 180, the base section 190, and the like is plastic. However, these sections may be formed of other materials.

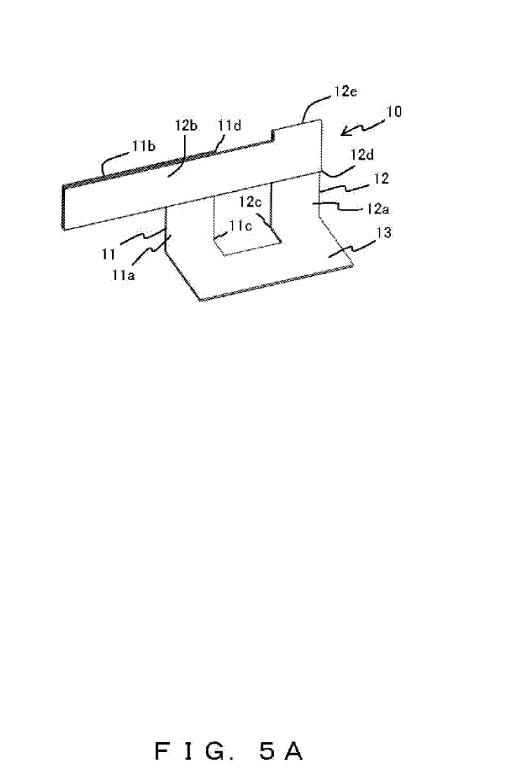

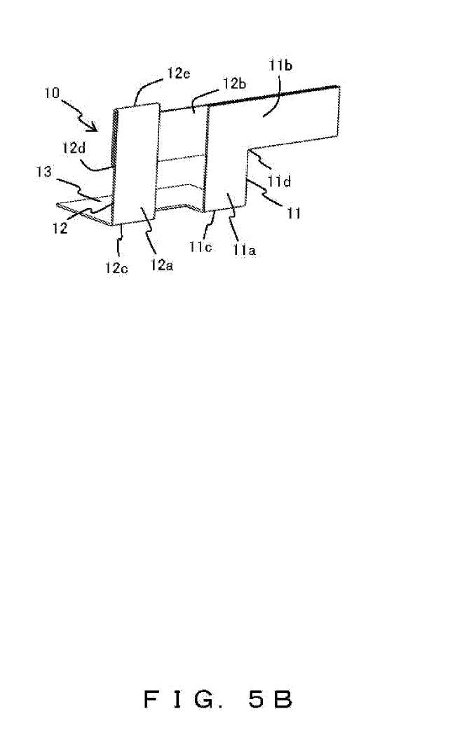

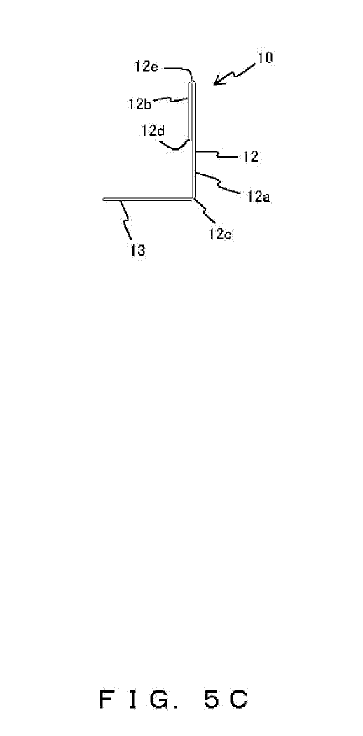

FIGS. 5A and 5B are main part perspective views showing the flexible wiring structure 10 according to the first embodiment.

FIG. 5C is a main par rear view showing the flexible wiring structure 10 according to the first embodiment.

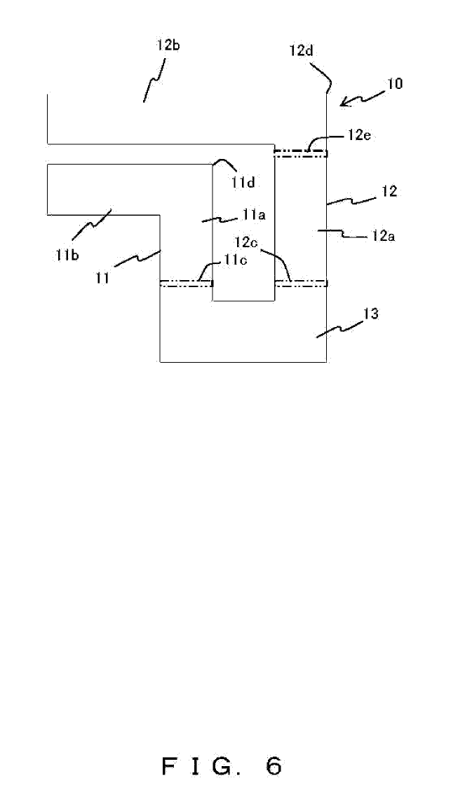

FIG. 6 is a main part exploded view showing the flexible wiring structure 10.

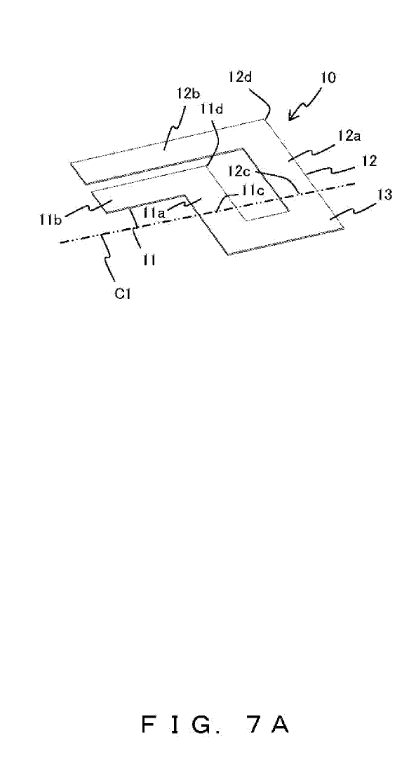

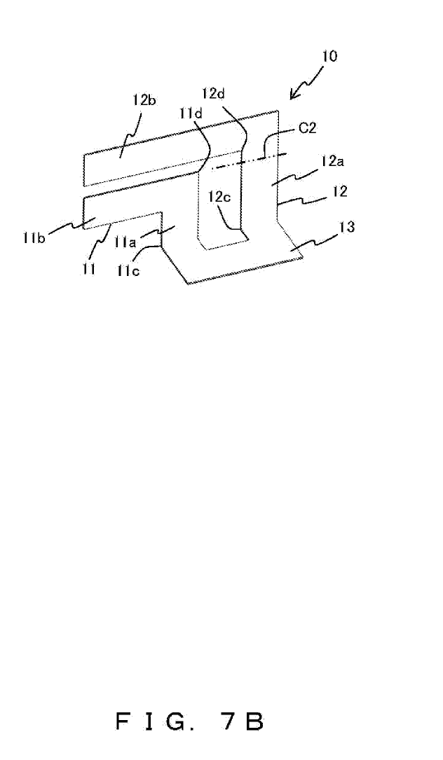

FIGS. 7A and 7B are explanatory diagrams for explaining a bending method for the flexible wiring structure 10.

As shown in FIGS. 5A to 5C, the flexible wiring structure 10 includes a first flexible wiring section 11, a second flexible wiring section 12, and a relay section 13.

As shown in FIG. 6, the first flexible wiring section 11 and the second flexible wiring section 12 are divided to be each formed in an L shape with the relay section 13 provided on one end side of an L-shaped section shown in FIGS. 5A to 7B of the flexible wiring structure 10. The first flexible wiring section 11 and the second flexible wiring section 12 are, for example, one-side flexible wires.

The first flexible wiring section 11 includes a first raised surface 11a raised from a plane of the relay section 13 via a first relay side bending section 11c provided on the relay section 13 side (along a valley fold Cl in FIG. 7A) and a first post-bend raised surface lib bent in a first bent section 11d, which is a bent section of the L-shaped section, from the first raised surface 11a.

The second flexible wiring section 12 includes a second raised surface 12a raised from the plane of the relay section 13 via a second relay side bending section 12c provided on the relay section 13 side (along the valley fold C1 in FIG. 7A) and a second post-bend raised surface 12b bent in a second bent section 12d, which is a bent section of the L-shaped section and provided above the first bent section 11d, from the second raised surface 12a and parallel to the first post-bend raised surface lib.

In the first flexible wiring section 11 and the second flexible wiring section 12, the first relay side bending section 11c and the second relay side bending section 12c may be provided in a boundary portion with the relay section 13. However, when easiness of bending in the first relay side bending section 11c and the second relay side bending section 12c is taken into account, it is desirable that a space is present between the first and second relay side bending sections 11c and 12c and the relay section 13. A space between the first flexible wiring section 11 and the second flexible wiring section 12 only may be determined according to, for example, the configuration of the imaging device 100.

The second post-bend raised surface 12b is folded back along a valley fold C2 as shown in FIG. 7B in a raised surface bending section 12e provided in the second raised surface 12a and overlaps the first post-bend raised surface 11b.

The relay section 13 is connected to a control board of a cellular phone, a small DSC, or the like, in which the imaging device 100 shown in FIG. 1 and the like is arranged, via a connector.

As shown in FIG. 1, a third bent section 11e bent along the outer periphery of the imaging device 100 is provided at an end of the first post-bend raised surface lib on the opposite side of the first raised surface 11a. A fourth bent section 12f bent along the outer periphery of the imaging device 100 is provided at an end of the second post-bend raised surface 12b on the opposite side of the second raised surface 12a.

In the flexible wiring structure 10, an L-shaped section same as the L-shaped section shown in FIGS. 5A to 7B is formed on the opposite side across the third bent section 11e and the fourth bent section 12f. On the opposite side, the flexible wiring structure 10 is indirectly connected to the imaging element 111 via the base substrate 112 of the imaging element unit 110. In the flexible wiring structure 10, the L-shaped sections do not have to be formed on both sides. The L-shaped section only may be formed on one side.

In the first embodiment explained above, the first flexible wiring section 11 and the second flexible wiring section 12 include the first raised surface 11a and the second raised surface 12a raised from the plane of the relay section 13 via the first relay side bending section 11c and the second relay side bending section 12c provided on the relay section 13 side. The second post-bend raised surface 12b of the second flexible wiring section 12 is folded back in the raised surface bending section 12e provided on the second raised surface 12a and overlaps the first post-bend raised surface 11b of the first flexible wiring section 11.

Therefore, by forming the flexible wiring structure 10 with a one-side flexible wire without using a both-side flexible wire, concerning reaction, the geometrical moment of inertia I=(bt³)/12, which is an indicator of easiness of bending, can be reduced to about ¼. Specifically, when the width of a flexible wire is represented as b and the thickness of the flexible wire is represented as t, by changing the both-side flexible wire to the one-side flexible wire, the thickness t is reduced to about ½ and the geometrical moment of inertia I is reduced to about ⅛. Even if two one-side flexile wires are used in the first flexible wire section 11 and the second flexible wiring section 12 and the geometrical moment of inertia I is doubled, the moment of inertia I is still about ¼.

Since the first post-bend raised surface 11b and the second post-bend raised surface 12b overlap, it is possible to realize a reduction in size through routing of a flexible wire.

Therefore, according to this embodiment, it is possible to provide the flexible wiring structure 10 and the imaging device 100 in which the reaction of a flexible wire can be suppressed and a reduction in size through routing of the flexible wire can be realized.

Further, since the flexible wiring structure 10 is formed with the one-side flexible wire without using the both-side flexible wire, it is also possible to obtain an effect that a bend R and the like can be reduced, an effect that the flexible wiring structure 10 is less easily broken and the durability of the flexible wiring structure 10 can be improved because a neutral surface of the bend is located on a copper wire, and an effect that cost can be reduced. Since the flexible wiring structure 10 is arranged in the imaging device 100, which is a single focus module having many limitations, in particular, in a certain height direction (incident direction), it is possible to more effectively realize a reduction in size of the imaging device 100.

In this embodiment, as shown in FIG. 1, the third bent section 11e is provided at the end of the first post-bend raised surface 11b on the opposite side of the first raised surface 11a. The fourth bent section 12f is provided at the end of the first post-bend raised surface 12b on the opposite side of the second raised surface 12a. Therefore, it is possible to realize a further reduction in size by routing the flexible wiring structure 10 in accordance with the shape of the imaging device 100 or the like.

### Second Embodiment

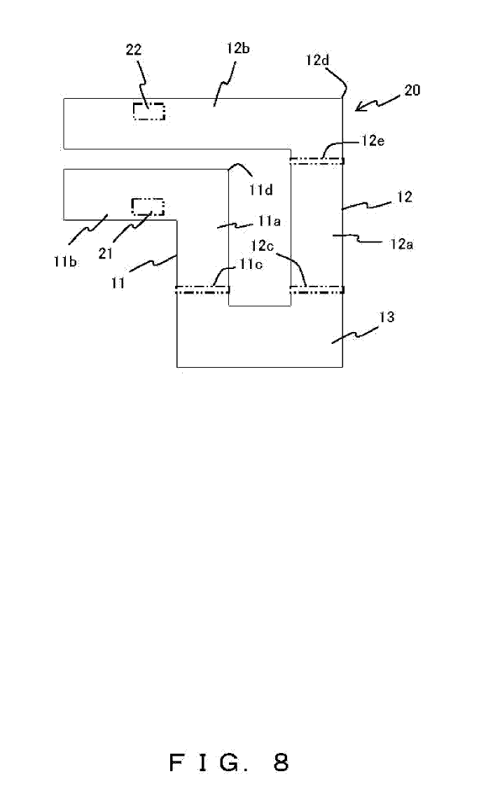

FIG. 8 is a main part exploded view showing a flexible wiring structure 20 according to a second embodiment.

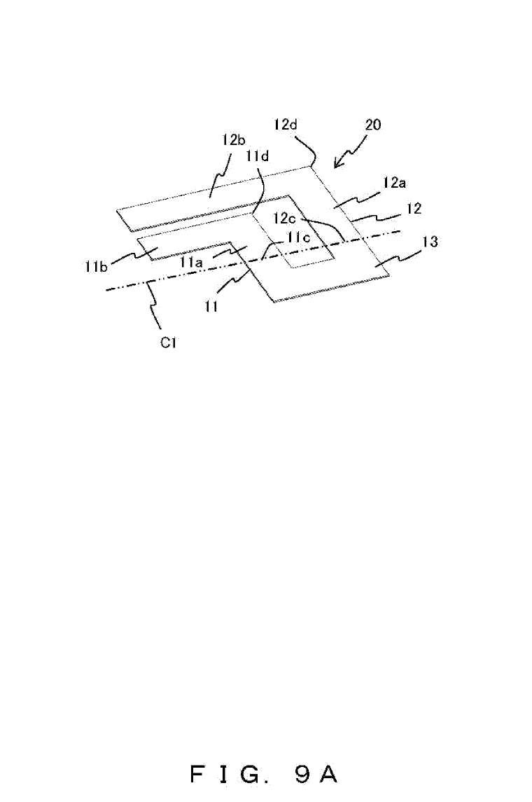

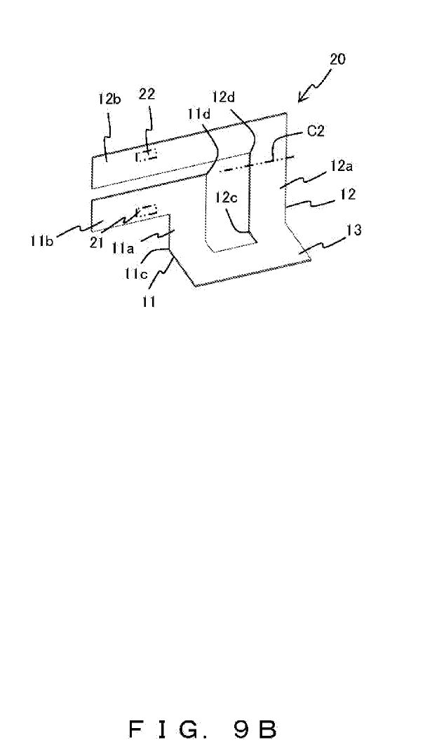

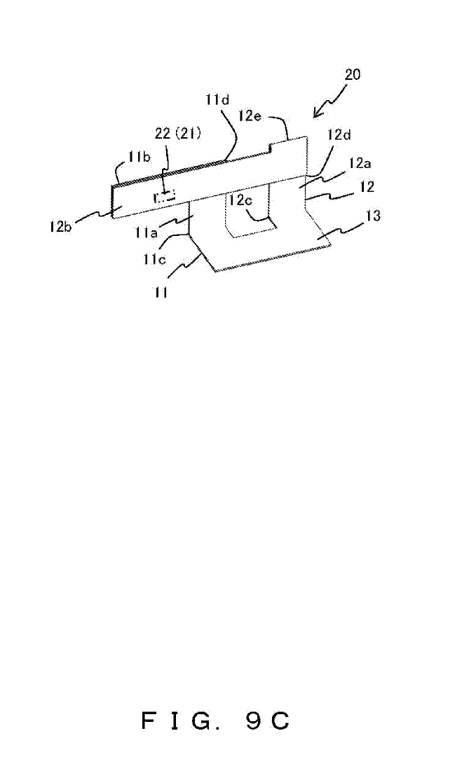

FIGS. 9A to 9C are explanatory diagrams for explaining a bending method for the flexible wiring structure 20 according to the second embodiment.

The flexible wiring structure 20 according to this embodiment is different from the flexible wiring structure 10 according to the first embodiment in that the first post-bend raised surface 11b and the second post-bend raised surface 12b are fixed to each other. Otherwise, the flexible wiring structure 20 is the same as the flexible wiring structure 10. Therefore, in this embodiment, explanation of components same as those in the first embodiment is omitted. In the figures, the same components are denoted by reference numerals and signs same as those in the first embodiment.

As shown in FIGS. 8 to 9C, the first post-bend raised surface 11b and the second post-bend raised surface 12b are fixed to each other in a soldered portion 21 indicated by an alternate long and two short dashes line provided on the first post-bend raised surface 11b and an insulated portion 22 indicated by an alternate long and two short dashes line provided on the second post-bend raised surface 12b.

The soldered portion 21 is formed on the surface of the first post-bend raised surface 11b by being arranged in, for example, a melted state during fixing. The insulated portion 22 is the surface of the second post-bend raised surface 12b and is, for example, polyimide.

The insulated portion 22 maybe provided on the first post-bend raised surface 11b and the soldered portion 21 may be provided on the second post-bend raised surface 12b. The first post-bend raised surface 11b and the second post-bend raised surface 12b can also be fixed by another fixing method such as bonding.

According to this embodiment, the same effects can be obtained concerning points same as those in the first embodiment.

In this embodiment, the first post-bend raised surface 11b and the second post-bend raised surface 12b are fixed to each other. Therefore, for example, since the strength of the flexible wiring structure 20 is increased by integrating the first flexible wiring section 11 and the second flexible wiring section 12, it is possible to realize a further reduction in size.

In this embodiment, the first post-bend raised surface 11b and the second post-bend raised surface 12b are fixed to each other in the soldered portion 21 provided on one of the first post-bend raised surface 11b and the second post-bend raised surface 12b and the insulated portion 22 provided on the other. Therefore, making use of the surfaces of, for example, polyimide of the first flexible wiring section 11 or the second flexible wiring section 12, it is possible to realize a reduction in man-hour in sticking the first post-bend raised surface 11b and the second post-bend raised surface 12b using an insulating tape or the like. It is also possible to realize a further reduction in size by using metal that is thinner but is stronger than a resin component.

### Third Embodiment

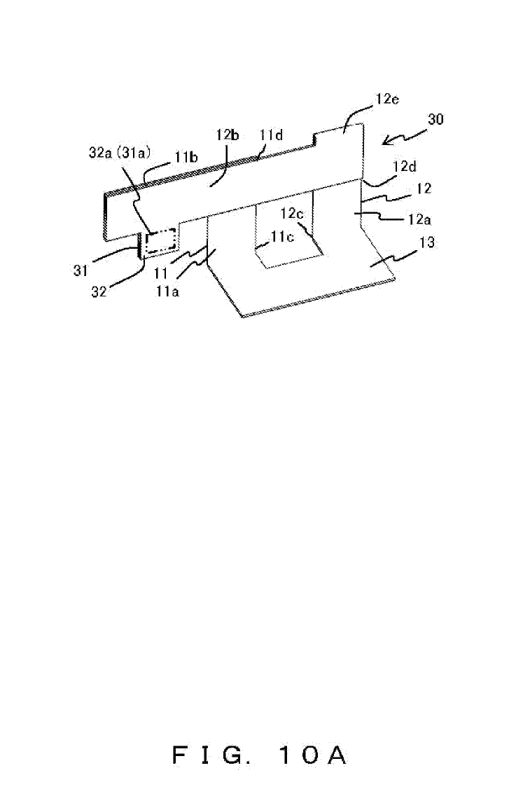

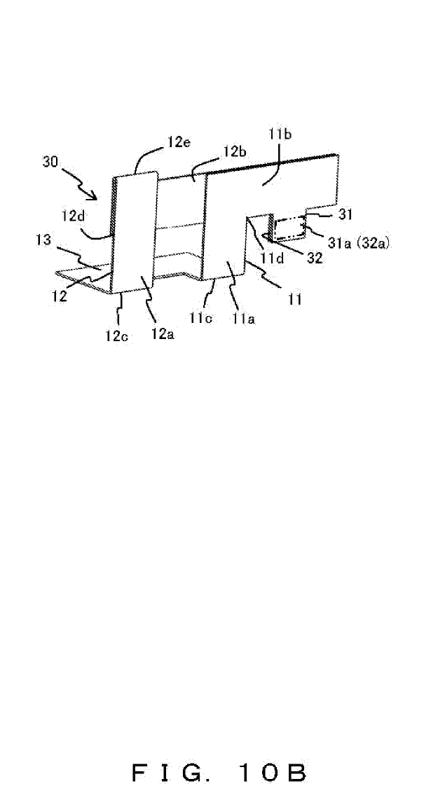

FIGS. 10A and 10B are main part perspective view showing the flexible wiring structure 30 according to a third embodiment.

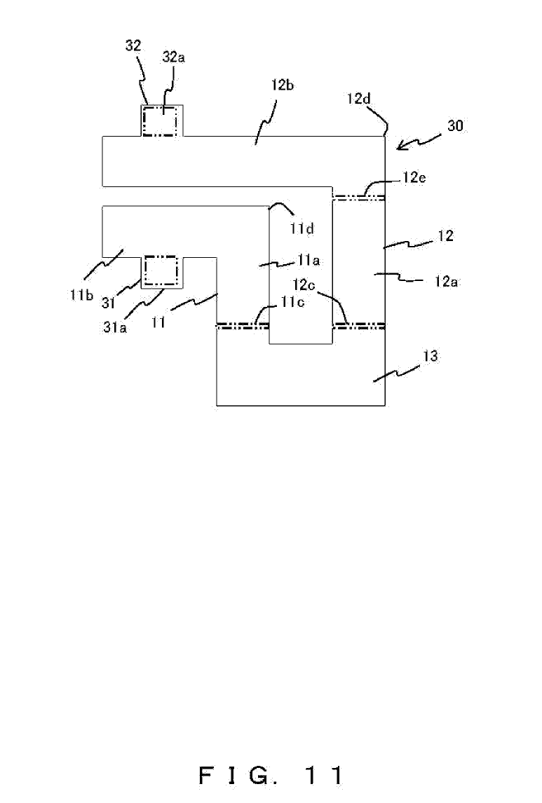

FIG. 11 is a main part exploded view showing the flexible wiring structure 30.

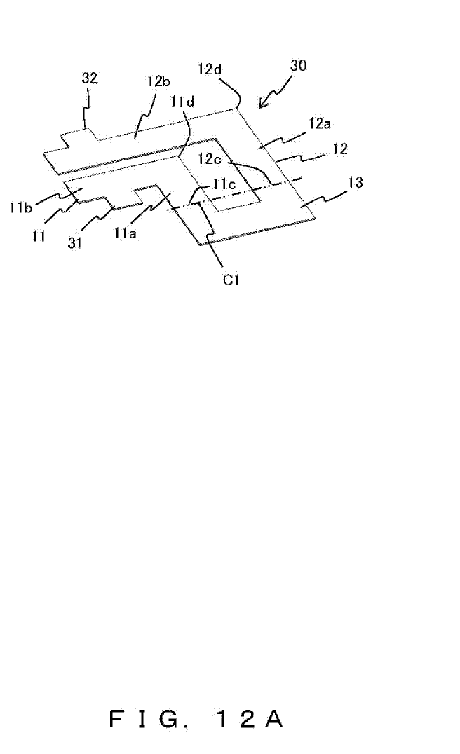

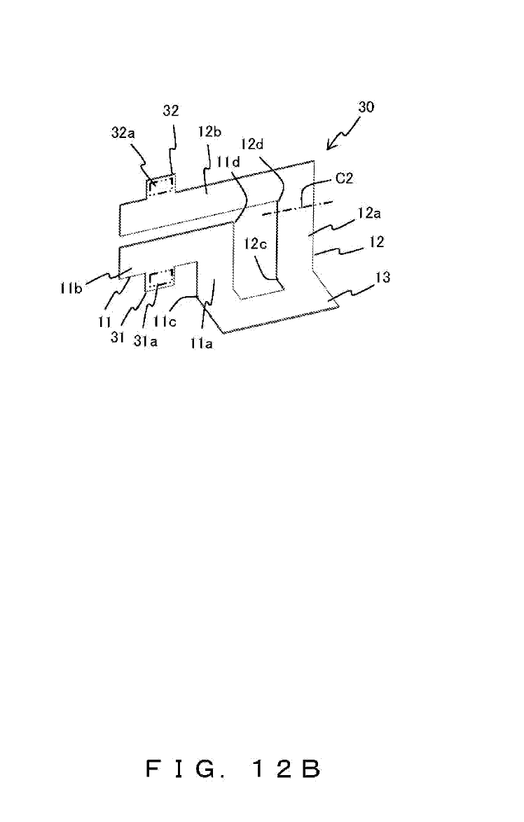

FIGS. 12A and 12B are explanatory diagrams for explaining a folding method for the flexible wiring structure 30.

The flexible wiring structure 30 according to this embodiment is different from the flexible wiring structure 10 according to the first embodiment in that extending sections 31 and 32 extending in a direction crossing the longitudinal direction of the first post-bend raised surface 11b and the second post-bend raised surface 12b are formed on the first post-bend raised surface 11b and the second post-bend raised surface 12b and the first post-bend raised surface 11b and the second post-bend raised surface 12b are fixed to each other in the extending sections 31 and 32. Otherwise, the flexible wiring structure 30 is the same as the flexible wiring structure 10. Therefore, in this embodiment, explanation of components same as those in the first embodiment is omitted. In the figures, the same components are denoted by reference numerals and signs same as those in the first embodiment.

As shown in FIGS. 10A to 12B, in the first post-bend raised surface 11b and the second post-bend raised surface 12b, the extending sections 31 and 32 extending to project in a downward direction after bending, which is an example of the direction crossing the longitudinal direction, are formed. In this embodiment, the extending sections 31 and 32 are formed in a rectangular shape. However, the extending sections 31 and 32 may be formed in other shapes. Depending on a device configuration of the imaging device 100 or the like, the extending sections 31 and 32 maybe formed to project in another direction such as an upward direction after bending.

The first post-bend raised surface 11b and the second post-bend raised surface 12b are fixed to each other in the extending sections 31 and 32. A fixing method is not limited. However, for example, as in the second embodiment, it is advisable to fix the first post-bend raised surface 11b and the second post-bend raised surface 12b each other in a soldered portion 31a indicated by an alternate long and two short dashes line provided on one of the first post-bend raised surface 11b and the second post-bend raised surface 12b and an insulated portion 32a indicated by an alternate long and two short dashes line provided on the other.

According to this embodiment, the same effects can be obtained concerning points same as those in the first and second embodiments.

In this embodiment, in the first post-bend raised surface 11b and the second post-bend raised surface 12b, the extending sections 31 and 32 extending in the direction crossing the longitudinal direction are formed. The first post-bend raised surface 11b and the second post-bend raised surface 12b are fixed to each other in the extending sections 31 and 32. Therefore, it is possible to prevent fixing portions such as the soldered portion 31a from occupying a space in a wiring region. Therefore, it is possible to improve wiring density.

In the embodiments, the example in which the flexible wiring structures 10, 20, and 30 are arranged in the imaging device 100 is explained. However, the flexible wiring structures 10, 20, and 30 can also be applied to other electronic devices.

Besides, the present invention is not limited to the embodiments and various alternations and modifications of the embodiments are possible without departing from the spirit of the present invention.

What is claimed is:

1. A flexible wiring structure comprising a first flexible wiring section and a second flexible wiring section divided with a relay section provided on one end side of an L-shaped section of a flexible wire having the L-shaped section, wherein
the first flexible wiring section includes a first raised surface raised from a plane of the relay section via a first relay side bending section provided on the relay section side and a first post-bend raised surface bent in a first bent section, which is a bent section of the L-shaped section, from the first raised surface,
the second flexible wiring section includes a second raised surface raised from the plane of the relay section via a second relay side bending section provided on the relay section side and a second post-bend raised surface bent in a second bent section, which is a bent section of the L-shaped section and provided above the first bent section, from the second raised surface and parallel to the first post-bend raised surface, and
the second post-bend raised surface is folded back in a raised surface bending section provided on the second raised surface and overlaps the first post-bend raised surface.

2. The flexible wiring structure according to claim 1, wherein a third bent section is provided at an end of the first post-bend raised surface on an opposite side of the first raised surface.

3. The flexible wiring structure according to claim 1, wherein a fourth bent section is provided at an end of the second post-bend raised surface on an opposite side of the second raised surface.

4. The flexible wiring structure according to claim 1, wherein the first post-bend raised surface and the second post-bend raised surface are integrated with each other to be fixed.

5. The flexible wiring structure according to claim 4, wherein the first post-bend raised surface and the second post-bend raised surface are fixed to each other in a soldered portion provided on one of the first post-bend raised surface and the second post-bend raised surface and an insulated portion provided on the other.

6. The flexible wiring structure according to claim 4,wherein
extending sections extending in a direction crossing a longitudinal direction are formed on the first post-bend raised surface and the second post-bend raised surface, and
the first post-bend raised surface and the second post-bend raised surface are fixed to each other in the extending sections.

7. An imaging device comprising:
a flexible wiring structure; and
an imaging element that is connected to the flexible wiring structure and images incident light and outputs an imaging signal, wherein
the flexible wiring structure includes a first flexible wiring section and a second flexible wiring section divided with a relay section provided on one end side of an L-shaped section of a flexible wire having the L-shaped section,
the first flexible wiring section includes a first raised surface raised from a plane of the relay section via a first relay side bending section provided on the relay section side and a first post-bend raised surface bent in a first bent section, which is a bent section of the L-shaped section, from the first raised surface,
the second flexible wiring section includes a second raised surface raised from the plane of the relay section via a second relay side bending section provided on the relay section side and a second post-bend raised surface bent in a second bent section, which is a bent section of the L-shaped section and provided above the first bent section, from the second raised surface and parallel to the first post-bend raised surface, and
the second post-bend raised surface is folded back in a raised surface bending section provided on the second raised surface and overlaps the first post-bend raised surface.

8. The imaging device according to claim 7, wherein a third bent section is provided at an end of the first post-bend raised surface on an opposite side of the first raised surface.

9. The imaging device according to claim 7, wherein a fourth bent section is provided at an end of the second post-bend raised surface on an opposite side of the second raised surface.

10. The imaging device according to claim 7, wherein the first post-bend raised surface and the second post-bend raised surface are integrated with each other to be fixed.

11. The imaging device according to claim 10, wherein the first post-bend raised surface and the second post-bend raised surface are fixed to each other in a soldered portion provided on one of the first post-bend raised surface and the second post-bend raised surface and an insulated portion provided on the other.

12. The imaging device according to claim 10, wherein
extending sections extending in a direction crossing a longitudinal direction are formed on the first post-bend raised surface and the second post-bend raised surface, and
the first post-bend raised surface and the second post-bend raised surface are fixed to each other in the extending sections.

13. The imaging device according to claim 7, further comprising:
an optical element that focuses incident light on an imaging surface of the imaging element;
a driving section that moves the imaging element onto a same plane as the imaging surface of the imaging element; and
a detecting section that detects a movement amount of the imaging element.

14. A flexible wiring method comprising:
forming a first flexible wiring section and a second flexible wiring section divided with a relay section provided on one end side of an L-shaped section of a flexible wire having the L-shaped section;
forming, in the first flexible wiring section, a first raised surface raised from a plane of the relay section via a first relay side bending section provided on the relay section side and a first post-bend raised surface bent in a first bent section, which is a bent section of the L-shaped section, from the first raised surface;
forming, in the second flexible wiring section, a second raised surface raised from the plane of the relay section via a second relay side bending section provided on the relay section side and a second post-bend raised surface bent in a second bent section, which is a bent section of the L-shaped section and provided above the first bent section, from the second raised surface and parallel to the first post-bend raised surface; and
folding back the second post-bend raised surface in a raised surface bending section provided on the second raised surface and placing the second-post-bend raised surface on the first post-bend raised surface.

15. The flexible wiring method according to claim 14, further comprising providing a third bent section at an end of the first post-bend raised surface on an opposite side of the first raised surface.

16. The flexible wiring method according to claim 14, further comprising providing a fourth bent section at an end of the second post-bend raised surface on an opposite side of the second raised surface.

17. The flexible wiring method according to claim 14, further comprising integrating the first post-bend raised surface and the second post-bend raised surface with each other to fix the first post-bend raised surface and the second post-bend raised surface.

18. The flexible wiring method according to claim 17, further comprising fixing the first post-bend raised surface and the second post-bend raised surface to each other in a soldered portion provided on one of the first post-bend raised surface and the second post-bend raised surface and an insulated portion provided on the other.

19. The flexible wiring method according to claim 17, further comprising:
forming extending sections extending in a direction crossing a longitudinal direction on the first post-bend raised surface and the second post-bend raised surface, and
fixing the first post-bend raised surface and the second post-bend raised surface to each other in the extending sections.
